(19) United States
(12) Patent Application Publication
(10) Pub. No.: US 2006/0283553 A1
(43) Pub. Date: Dec. 21, 2006

(54) PLASMA CHAMBER INSERT RING

(75) Inventors: Shawming MA, Sunnyvale, CA (US); Mahmoud DAHIMENE, Sunnyvale, CA (US); Claes BJORKMAN, Mountain View, CA (US)

Correspondence Address: Patent Counsel;Applied Materials, Inc., P.O. Box 450A, Santa Clara, CA, 95052, US

(73) Assignee: APPLIED MATERIALS, INC., Santa Clara, CA (US)

(21) Appl. No.: 11/468,270

(22) Filed: Aug. 29, 2006

Related U.S. Application Data
(62) Division of application No. 10/106,008, filed on Mar. 21, 2002.
(60) Provisional application No. 60/340,759, filed on Dec. 11, 2001.

(51) Int. Cl. H01L 21/306; C23C 16/00

(52) U.S. Cl. 156/345.51; 118/728; 156/914

(57) ABSTRACT

Methods and apparatuses for reducing electrical arcing currents or electron emissions to a wafer or to components in a plasma chamber are provided. An insert for use in a process chamber having a wafer support is disclosed. The insert comprises a composite member formed of a first material, such as for example, silicon, and a second material, such as for example, SiO₂, having a greater electrical impedance than the first material. The composite member has a surface which is adapted to be disposed adjacent to the wafer support, and which is made of the second material. In one aspect, the process chamber further has an outer member adapted to surround the wafer support. The composite member has a surface which is adapted to be disposed adjacent to the outer member and which is made of the second material. In another aspect, the composite member has a surface which is adapted to be disposed adjacent to a semiconductor wafer and which is made of the second material.

### CROSS REFERENCE TO RELATED APPLICATIONS

This application claims priority from U.S. Provisional Patent Application No. 60/340,759, filed on Dec. 11, 2001 under Applicant's Docket No. 4996/ETCH/DICP-PROV.

### FIELD OF THE INVENTION

This invention relates to a plasma chamber for semiconductor wafer processing systems, and more particularly, to improved devices and methods for reducing electrical arcing or electron emission in a plasma chamber.

### INTRODUCTION

Plasma chambers for semiconductor wafer processing systems commonly include wafer supports for supporting semiconductor wafers within these chambers. Some wafer supports are pedestals, typically made of aluminum or stainless steel, having a top planar surface on which the wafer can rest. Other wafer supports include both pedestals and electrostatic chucks which are typically used for securing the wafers in place. An electrostatic chuck (ESC) generally is supported on the pedestal and includes a dielectric layer having an imbedded electrode or electrodes. To produce a clamping force between the wafer and a support surface of the chuck, the electrode is connected to a power source, usually a high voltage, DC power supply. The wafer support assembly is typically positioned centrally within a process chamber for accomplishing chemical vapor deposition (CVD), physical vapor deposition (PVD), or etch processes.

To facilitate the efficient use of these processes, a plasma is often formed in the process chamber proximate the surface of the process wafer. To generate such a plasma, a process gas is usually introduced into the process chamber and energy is coupled to the process gas to form the plasma. The energy is typically supplied by an antenna or an electrode coupled to an RF power source. For example, in a capacitively coupled, dual electrode plasma chamber, RF power may be applied between the grounded chamber walls and the pedestal supporting the ESC.

In one operation, a wafer is placed upon the support surface of the ESC, a process gas is introduced in the process chamber, the plasma is ignited by coupling the plasma generating energy to the process gas, and, lastly, a chucking voltage is applied to the ESC electrode. Typically, the chucking voltage is applied between the electrode and the grounded process chamber walls. As such, the plasma, being conductive, refers the wafer to the chamber walls with a small voltage drop across dark space regions that are formed between the wafer and the plasma, and the plasma and the chamber walls. Consequently, charge accumulates on the support surface of the dielectric layer and on the wafer surface that faces the support surface. The charges on each surface are oppositely polarized. As a result, Coulomb forces attract the charges and retain the wafer on the support surface of the ESC.

An ESC can include a flex circuit which in turn includes a thin conductive layer, e.g., copper, sandwiched between upper and lower dielectric layers. The dielectric layers are typically formed of polyimide or some other flexible dielectric material. In some embodiments, the flex circuit has thickness of between six and nine mils (0.15 to 0.23 mm). A laminant-type ESC is disclosed in greater detail in U.S. Pat. No. 5,822,171 to Shamouilian et al and assigned to the same assignee as the present invention.

A flex circuit is often adhered to the top surface of a pedestal using an adhesive such as phenolic butyral. The pedestal is typically aluminum, but can be fabricated of other materials such as stainless steel. In some embodiments, the flex circuit has a diameter that is 4 to 10 millimeters smaller than the diameter of a process wafer such that the wafer completely covers the surface of the ESC. As such, the wafer protects the ESC from exposure to the plasma.

Other conventional components of the process chamber that function in cooperation with the wafer support can include an insulating ring and a focus or top ring. In some instances, the insulating ring and top ring are fabricated as a single component. The insulating ring typically has an annular shape and rests upon the pedestal and circumscribes the ESC. The top ring typically also has an annular shape which rests upon the insulating ring and circumscribes the ESC and wafer.

In some embodiments, the portion of the wafer that overhangs the edge of the ESC is generally spaced apart from the focus ring and the insulating ring to facilitate good seating of the wafer onto the ESC. However, because of the gap formed between these components, undesirable arcing of electrical current from the ESC or the pedestal to the wafer edge can occur. This arcing can cause pitting damage to the wafer edge, thus reducing wafer yield.

Before describing the invention, the overall operation of one example of a conventional magnetically-enhanced plasma chamber will be explained. The present invention, however, may be used in a variety of plasma chambers. FIG. 1 shows a magnetically-enhanced, dual electrode, capacitively-coupled plasma chamber 100 suitable for either etching or chemical vapor deposition (CVD). Plasma may also be generated using inductively coupled coils, electron guns, microwave generators and other plasma sources.

The vacuum chamber 100 is enclosed by a cylindrical side wall 102, a circular bottom wall 104, and a circular top wall or lid 106. The lid 106 and bottom wall 104 may be either dielectric or metal. An electrically grounded anode electrode 108 is mounted at the bottom of the lid 106. The anode electrode 108 may be perforated to function as a gas inlet through which process gases enter the chamber. The side wall 102 may be either dielectric or metal. If it is metal, the metal is preferentially a non-magnetic material such as anodized aluminum so as to not interfere with the magnetic field created by electromagnet coils outside the chamber. If the side wall is metal, it can function as part of the anode.

The semiconductor wafer or workpiece 110 is mounted on a cathode electrode 112 or pedestal, which, in turn, is mounted in the lower end of the chamber. A vacuum pump, not shown, exhausts gases from the chamber through an exhaust manifold 114 and maintains the total gas pressure in the chamber at a level low enough to facilitate creation of a plasma, typically in the range of 10 millitorr to 20 torr, with pressures at the lower and higher ends of the range being typical for etching and CVD processes, respectively.

An RF power supply 116 is connected to the cathode electrode 112 or pedestal through a RF feedthrough 117 and a series coupling capacitor 118. The RF power supply 116 provides an RF voltage between the cathode electrode 112 and the grounded anode electrode 108 which excites the gases within the chamber into a plasma state. The plasma body has a time-average positive DC potential or voltage relative to the cathode or anode electrodes which accelerates ionized process gas constituents to bombard one or both of the cathode and anode electrodes.

Magnetic enhancement of the plasma is often implemented by a DC magnetic field in the region between the cathode and anode electrodes. The direction of the magnetic field is transverse to the longitudinal axis of the chamber, i.e., transverse to the axis extending between the cathode and anode electrodes. Various arrangements of permanent magnets or electromagnets are conventionally used to provide such a transverse magnetic field. One such arrangement is the pair of coils 120 shown in FIG. 1, disposed on opposite sides of the cylindrical chamber side wall 102. The two coils 120 are connected in series and in phase to a DC power supply, not shown, so that they produce transverse magnetic fields which are additive in the region between the two coils. These magnetic fields may be rotated mechanically or electronically to facilitate uniformity. The field strengths may also be varied.

To maximize the rate of the plasma-enhanced semiconductor fabrication process being performed in the plasma chamber, it normally is considered desirable to minimize any coupling of RF power to the plasma from areas of the pedestal or cathode electrode 112 other than the area directly behind (i.e., covered by) the wafer 110. In other words, it normally is considered desirable to minimize coupling of RF power from the sides of the cathode or, if the cathode diameter is larger than the wafer diameter, from the portion of the upper surface of the cathode which surrounds the wafer perimeter. This concentrates the ion flux from the plasma sheath to the cathode electrode 112 within the cathode surface area occupied by the wafer 110.

For example, FIG. 1 shows a cylindrical dielectric or insulating shield 122 surrounding the sides of the cylindrical cathode electrode 112, and a dielectric or insulating ring 124 covering the portion of the cathode top surface which surrounds the wafer 110. In chambers for processing silicon (Si) wafers, high purity quartz is a commonly used dielectric material because the quartz typically will not release significant contaminants into the chamber. RF power coupling can be minimized by increasing the thickness of the dielectric and choosing dielectric material of low dielectric constant. In such a design, the area of the plasma sheath facing the cathode can correspond more closely to the area of the wafer.

The spatial uniformity of ion flux over the wafer 110 can be further improved by replacing the insulating ring 124 (FIG. 1) with a modified insulating ring. Referring to FIG. 2, an insulating ring 202 is shown which is adapted to surround an ESC 206. The insulating ring 202 has a thinner annular portion 204 adjacent to the edge of the ESC 206 immediately outside the perimeter of the wafer 110. The annular portion 204 is typically sufficiently thin—hence, its electrical impedance at the frequency (typically 13.56 Mhz) of the RF power supply 116 (FIG. 1) is sufficiently low—such that enough RF power is coupled from the RF power supply 116 to the plasma through the annular portion 204 (FIG. 2) to cause the plasma sheath above the wafer surface to extend radially outward over the annular portion 204.

A silicon insert ring 208 covers the thin portion 204 of the insulating ring 202 and is disposed adjacent to a vertical side wall 217 of the insulating ring 202. The insert ring 208 can be constructed of pure silicon, silicon or polysilicon. It is noted that these materials etch like the wafer. (Although constructed of silicon, it is believed that an extremely thin film of less than 100 angstroms (Å) thickness of silicon dioxide (SiO₂) can naturally form on the surfaces of the ring 208 due to normal oxidation resulting from exposure to oxygen or the atmosphere.) A ring of this construction is intended to provide a plasma profile which is more uniform at the edge of the wafer 110. In other words, the insert ring 208 can increase the effective size of the wafer to the plasma.

Another purpose of the insert ring 208 is to protect the perimeter edge 226 of the ESC 206 from contacting the plasma which might otherwise result in etching damage to the ESC. Yet another purpose of the insert ring 208 is to protect the thin portion 204 of the insulating ring 202 from erosion by the silicon dioxide etch process, since the quartz ring 202 is chemically similar to the silicon dioxide being etched on the silicon wafer 110. In some etch processes, silicon can etch at a rate at least ten times slower than the etch rate of quartz. When the insert ring 208 begins to acquire a noticeably concave surface due to the etch process, the ring can be readily replaced. Furthermore, the useful life of the insert ring 208 can be doubled by inverting it after the top surface becomes concave.

The insert ring 208 is frequently made of high purity material to minimize the release of contaminants into the chamber. For maximum purity, one design incorporates single crystal silicon having a silicon purity in excess of 99% silicon. Other designs requiring larger insert rings may incorporate a polysilicon material.

Referring still to FIG. 2, the ESC 206 is mounted on the pedestal or electrode 112. The pedestal 112 is typically aluminum, but can be fabricated of other materials such as stainless steel. Typically the perimeter edge 226 of the ESC 206 has a diameter that is 4 to 10 millimeters smaller than the diameter of the process wafer 110 such that the wafer 110 completely covers the surface of the ESC 206 and extends with an overhanging edge 224. As such, the wafer 110 protects the ESC 206 from exposure to the plasma.

Mounted over the insulating ring 202 is top ring 210 having a silicon top surface 218 adapted to face the plasma region 220 and remove fluorine radicals from the plasma. The top ring 210 extends in height above the wafer 110 and has a slope leading away from the wafer 110. Such a geometric configuration can strengthen a component of the electric field which is perpendicular to the magnetic field in the region over the edge of the wafer 110. Thus this can increase an amount of plasma which may be generated at the peripheral portion of the wafer 110 which in turn permits a more uniform etching rate or deposition rate over the entire surface of the wafer 110.

The silicon top surface 218 has an inner perimeter edge 222 spaced from and surrounding the overhanging wafer edge 224 when the wafer 110 is placed on the ESC 206. The insert ring 208 is adapted to be positioned between the ESC perimeter edge 226 and the top ring inner perimeter edge 222 and to be seated on the thin portion 204 of the insulating ring 202.

The overhanging edge 224 of the wafer 110 is generally spaced apart from the top surface of the insert ring 208 in a parallel, spaced-apart relationship. As such, a vertical gap 212 is formed between the overhanging edge 224 of the wafer 110 and the insert ring 208. The gap 212 serves to ensure that the wafer seats firmly on the ESC 206 and not on the insert ring 208. Additionally as a result of manufacturing tolerances, there can exist horizontal gaps 214 and 216 separating respectively the ESC perimeter edge 226 and the insert ring 208 and the insulating ring vertical side wall 217 and the insert ring 208.

It has been recognized by the present inventors that one problem that can arise with this prior design relates to the electrical arcing or electron emissions between the wafer 110 and the insert ring 208. As shown in FIG. 2 by the vectors j⁻, a current path can be established from the ESC 206 through the insert ring 208 across the vertical gap 212 to the edge of the wafer 110. This current can result in pitting damage to the edge portion of wafer 110 thus reducing wafer yield. As further shown by the vectors j⁻ in FIG. 2, arcing or electron emissions can occur across the gaps 214 and 216 between the ESC 206 and insert ring 208 as well as between the insulating ring 202 and the insert ring 208. Because the ESC 206 can be either positively or negatively charged with respect to the adjacent components, electron flow can occur in either direction across the gaps 212, 214, and 216. Nevertheless, this electron flow can result in pitting damage to the rings 202 and 208. Moreover, this pitting can result in pulverization of silicon particles which can contaminate the wafer 110.

FIG. 3 shows a known alternative design for an ESC and insert arrangement. The insert ring 208 rests on a ledge 219 of an ESC 215. A thin portion 227 of an insulating ring 225 has a horizontal upper surface 223 which is intentionally constructed to be below the ledge 219 of the ESC 215. Thus a vertical gap 221 is created between the upper surface 223 and the insert ring 208. Again, it has been recognized by the present inventors that electrical arcing or electron emissions as shown by the vector j⁻ can cross the vertical gap 221 thus providing a further source of pitting damage to the rings 225 and 208 as well as a further source of silicon particles for possible wafer contamination.

### SUMMARY

An insert for use in a process chamber having a wafer support is provided. The insert comprises a composite member comprised of a first material and a second material, the second material having a greater electrical impedance than the first material. The composite member has a surface which is adapted to be disposed adjacent to the wafer support, and which is made of the second material having a thickness in excess of 100 Å, in one embodiment.

In one aspect, the process chamber further has an outer member adapted to surround the wafer support. The composite member has another surface which is adapted to be disposed adjacent to the outer member. This surface also is made of the second material having a thickness in excess of 100 Å, in one embodiment.

In another aspect, the ESC is adapted to receive a wafer. The composite member has another surface which is adapted to be disposed adjacent to the wafer. This surface also is made of the second material having a thickness in excess of 100 Å in one embodiment.

In another aspect, the second material is SiO₂, and the first material is SiC, Al₂O₃, Y₂O₃ or Si having a purity of at least 99% Si, in one embodiment.

In another embodiment, the outer member comprises an insulating ring having a vertical side wall and a horizontal upper surface. Composite member surfaces are adapted to be disposed adjacent to either or both of the vertical side wall or the horizontal upper surface.

In another aspect, the wafer support has a perimeter edge and is adapted to receive a wafer having a overhanging wafer edge which overhangs the wafer support perimeter edge. A composite member surface is adapted to be disposed adjacent to the overhanging wafer edge.

In yet another embodiment, the insert comprises a member having a generally annular shape and constructed of a first material. The member has a top surface of a generally planar shape, a bottom surface of a generally planar shape, an outer surface of a generally cylindrical shape and an inner surface of a generally cylindrical shape. The member is adapted for placement in the chamber so that at least a part of the inner surface is adjacent to the wafer support perimeter edge. The member further has a layer of a second material having a thickness in excess of 100 Å and having a greater electrical impedance than the first material. The layer is disposed on one or more of the following: the top surface, the bottom surface, the outer surface or the inner surface.

There are additional aspects to the present inventions. It should therefore be understood that the preceding is merely a brief summary of some embodiments and aspects of the present inventions. Additional embodiments and aspects of the present inventions are referenced below. It should further be understood that numerous changes to the disclosed embodiments can be made without departing from the spirit or scope of the inventions. The preceding summary therefore is not meant to limit the scope of the inventions.

### BRIEF DESCRIPTION OF THE DRAWINGS

FIG. 1 is a cross-sectional view of a conventional plasma chamber.

FIG. 2 is a cross-sectional view of a known arrangement for a portion of a plasma chamber system comprising a wafer, ESC, insert ring and related components.

FIG. 3 is an enlarged cross-sectional view of the wafer, ESC, insert ring and related components of a conventional plasma chamber of a different design.

FIG. 4 is a cross-sectional view of a plasma chamber including an insert ring according to one embodiment of the present invention.

FIG. 5 is an enlarged, cross-sectional view of an insert ring in accordance with one embodiment of the present invention, along with selected other plasma chamber components.

FIG. 6a is an enlarged, cross-sectional view of an insert ring in accordance with another embodiment of the present invention, along with selected other plasma chamber components.

FIG. 6b is a top plan view of the insert ring, wafer and outer member of FIG. 6a.

FIGS. 7a-7c are enlarged cross-sectional views of insert rings in accordance with other embodiments of the present invention.

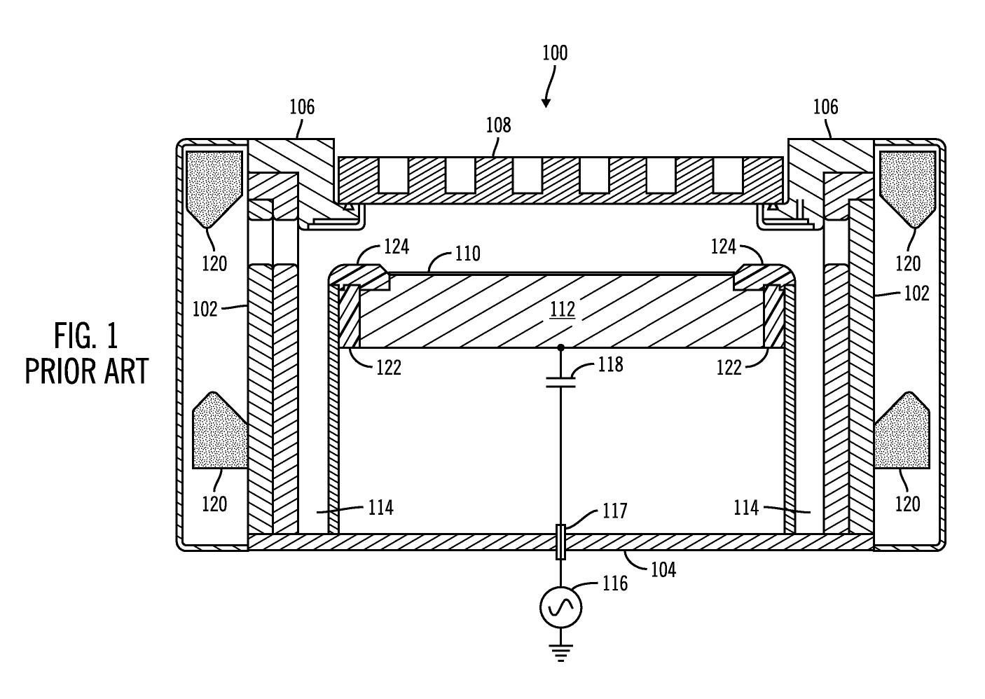

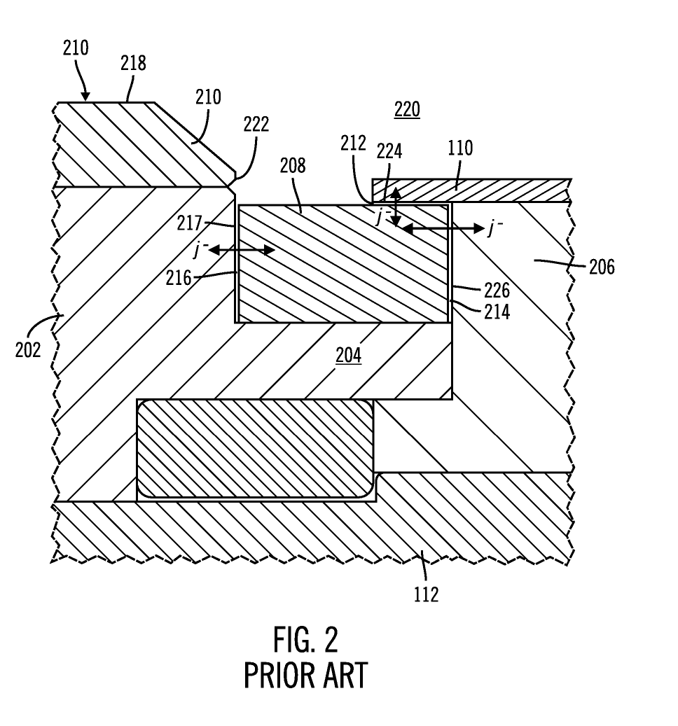

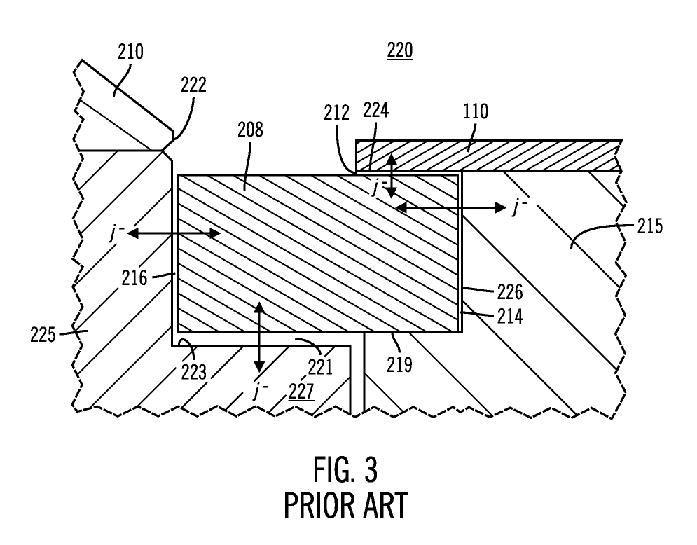

### DETAILED DESCRIPTION OF ILLUSTRATIVE EMBODIMENTS

In the following description, reference is made to the accompanying drawings which form a part hereof and which illustrate several embodiments of the present invention. It is understood that other embodiments may be utilized and structural and operational changes may be made without departing from the scope of the present invention.

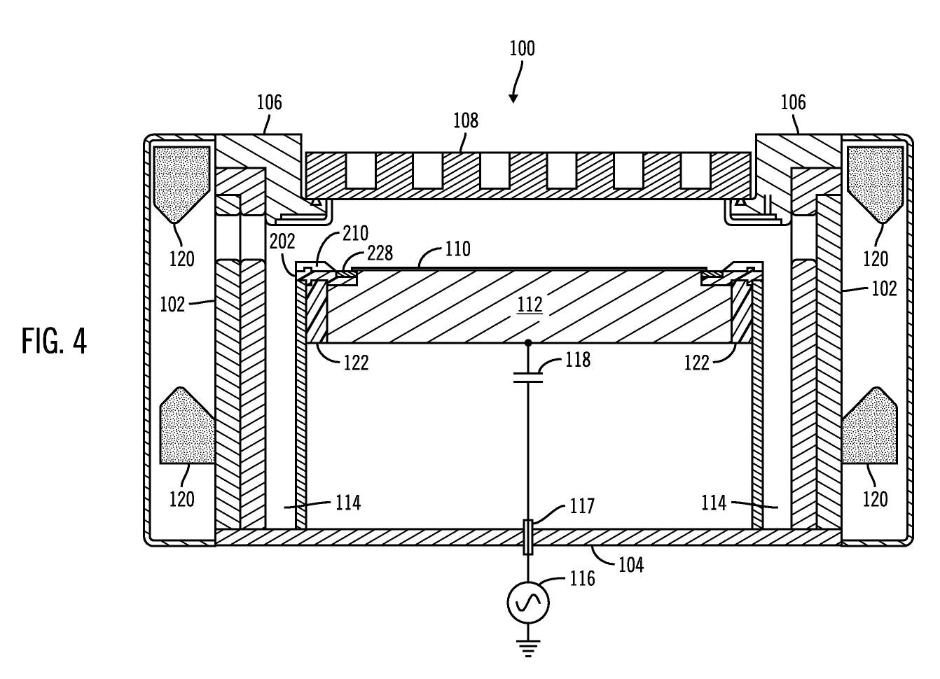

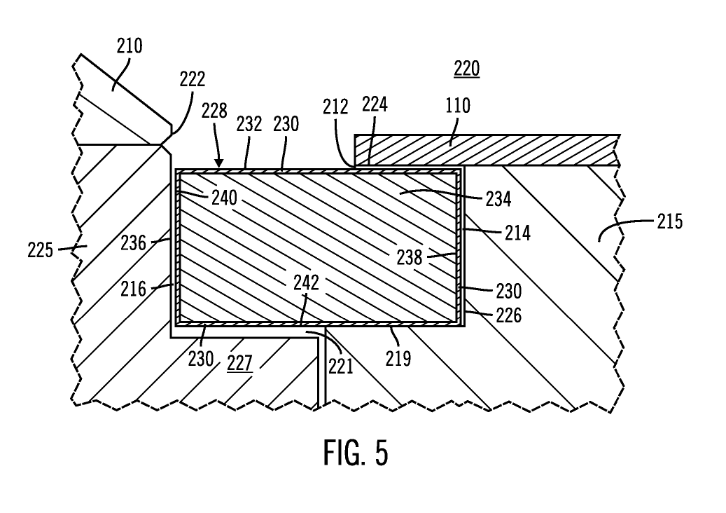

FIGS. 4 and 5 show an embodiment of the subject invention which can reduce or eliminate the previously-described, undesirable arcing or electron emission effect. A new insert ring 228 is disclosed which has a top planar surface 232 which, in one embodiment, is 6 mm in width. A portion of the top surface 232 is adapted to face the overhanging edge 224 portion of the wafer 110 in a parallel, spaced-apart relationship separated by the gap 212. Another portion of the top surface 232 is adapted to be exposed to the plasma region 220. The insert ring 228 further has a cylindrically-shaped inner surface 238 which is adjacent to the perimeter edge 226 of the ESC 206. A cylindrically-shaped outer surface 240 of the insert ring 228 defines a diameter which is smaller than the diameter defined by a vertical side wall 236 of the insulating ring 225, and which is adapted to permit a bottom planar surface 242 of the insert ring 228 to be seated on the ledge 219 of the ESC 215.

The ring 228 comprises a composite member formed of a first and a second material wherein the second material has greater electrical impedance than the first material. In one embodiment, a body 234 of the ring 228 is constructed of silicon having a purity of at least 99%. An insulating film of SiO₂ is used to form a layer 230 on the body 234. In this embodiment, the layer 230 has a thickness in excess of 100 Å, and more preferably in excess of 1,000 Å, and is disposed on preferably all surfaces, i.e. the top surface 232, the inner surface 238, the outer surface 240 and the bottom surface 242 of the insert ring 228. SiO₂ has electrically insulating properties, and accordingly the layer 230 reduces or eliminates the current or electron flow across the gaps 212, 214 and 216. Having the layer 230 disposed on the bottom surface 242 likewise may serve to reduce electron flow across the gap 221.

Because a portion of the top surface 232 of the insert ring 228 is exposed to the plasma 220, the SiO₂ layer 230 on that portion may be etched away or otherwise removed relatively rapidly. The residual exposed portion of the insert ring 228 however is constructed of silicon, and thus the lifetime of the ring can be expected to be the same as known silicon rings, because silicon remains the major material consumed. Moreover, those portions of the SiO₂ layer which are adjacent to the wafer and the ESC or adjacent to the gaps 214, 216, 221 may not be exposed to the plasma directly, and thus it is anticipated that the lifetime of the remaining SiO₂ layer will be enhanced.

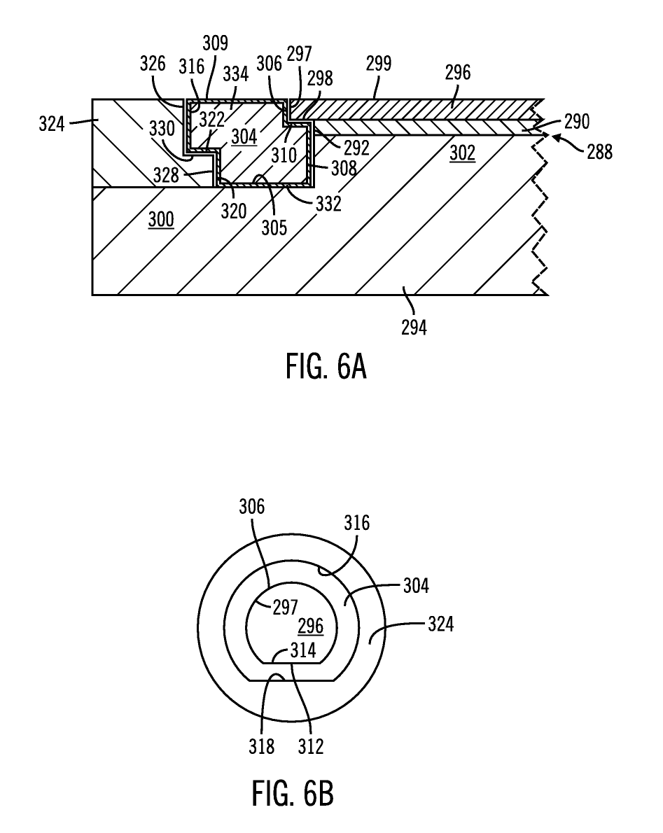

FIGS. 6a and 6b show an alternative embodiment of the present invention used in a plasma chamber of a different design. A wafer support 288 is comprised of an ESC 290 having a perimeter edge 292 and a pedestal or electrode 294 on which the ESC is disposed. The electrode 294 has a flange portion 300 and a raised portion 302 on which the ESC 290 is disposed. A semiconductor wafer 296 having a wafer perimeter edge 297 is seated on the ESC 290 and has a diameter which is larger than the ESC 290 such that an overhanging edge 298 of the wafer 296 overhangs the ESC perimeter edge 292.

Adjacent to the wafer 296, the ESC 290 and the raised portion 302 of the electrode 294 is a generally annular-shaped insert ring 304 having a bottom surface 305 which seats on the flange portion 300 of the electrode 294. The insert ring has an outer upper vertical surface 316 and an outer lower vertical surface 320 which are connected by a horizontal ledge 322. Similarly, the ring 304 has an inner upper vertical surface 306 and an inner lower vertical surface 308 which are connected by a horizontal ledge 310. Thus the upper inner surface 306 is spaced apart from the wafer perimeter edge 297; the insert ring ledge 310 is spaced apart from the overhanging wafer edge 298; and the lower inner surface 308 is spaced apart from the raised portion 302 of the electrode 294. A top surface 309 of the ring 304 forms a common plane with the top surface 299 of the wafer 296.

As best seen in FIG. 6b, while the inner upper surface 306 of the insert ring 304 is generally cylindrical in shape, it nevertheless has an inner orientation flat 312 which mates with an orientation flat 314 of the wafer edge 297. Similarly while the insert ring 304 has an outer upper surface 316 which is generally cylindrical in shape, it also nevertheless has an outer orientation flat 318 which is generally parallel to the inner orientation flat 312.

Referring again to FIG. 6a, an outer member 324 surrounds the insert ring 304 and has an upper inner vertical surface 326 and lower inner vertical surface 328 which are connected by a horizontal ledge 330. These surfaces are disposed so that they mate with the upper and lower outer surfaces 316, 320 of the insert ring 304 in a parallel, spaced-apart relationship.

The insert ring 304 comprises a composite member formed of a first and a second material wherein the second material has greater electrical impedance than the first material. A body 334 of the ring 304 is constructed of silicon having a purity of at least 99%. An insulating film of SiO₂ is used to form a layer 332 on the body 334. In the embodiment of FIG. 6a, the SiO₂ layer 332 is disposed on all surfaces of the insert ring 304 thus preventing or inhibiting electron flow between the insert ring 304 and any one or all of the outer member 324, the ESC 290, the electrode 294 and the wafer 296.

Although the embodiments of FIGS. 5 and 6a include layers on all surfaces of the rings 228, 304, it should be appreciated that other embodiments may have the layers disposed on fewer than all of the surfaces or on only a portion of one or more surfaces. Moreover although the bodies 234, 334 are made of silicon, other materials can be used as well. For example, the bodies can be manufactured of materials such as SiC, Al₂O₃, or Y₂O₃.

Traditionally during the manufacturing of known silicon rings, a layer of SiO₂ would be grown on the outside of the ring. Then the layer would be removed from the ring by using a wet etch process in order to make the surface smooth and achieve a ring constructed of relatively pure silicon. Thus, manufacturing the improved insert ring can be accomplished with relative ease. After the wet etch process, a SiO₂ layer having a thickness which is greater than the previously-removed layer can be accomplished by growing the film by thermal oxidation. However it should be appreciated by those skilled in the art that there are alternative methods by which a SiO₂ layer may be placed on a silicon ring. Nevertheless, thermal oxidation results in a good film quality with a relatively uniform thickness. There need not be a major change in the manufacturing process for these improved insert rings; it is anticipated that adding an oxidation step (and in the case where it is desired that not all sides be covered, a surface oxide removal step for the other sides of the ring) to the process flow will be sufficient.

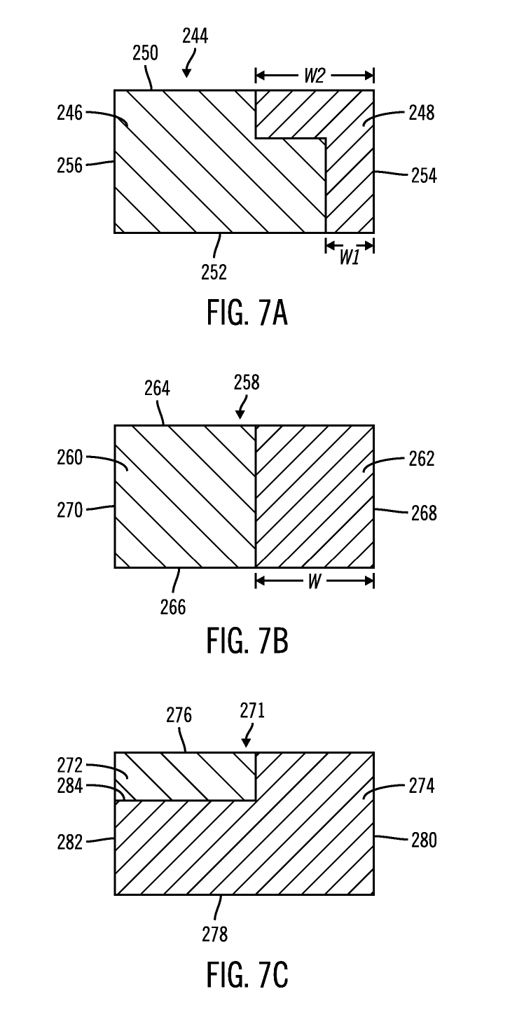

The insert rings of FIGS. 5 and 6a are composite members formed of a first and a second material wherein the material having the greater electrical impedance forms the film layers 230, 332. Other embodiments need not comprise film layers, however, and may involve different cross-sectional geometries than that of film layers. FIG. 7a shows a composite member insert ring 244 comprised of a first part 246 constructed of a first material and a second part 248 constructed of a second material having a greater electrical impedance than the first material.

The insert ring 244 has a generally rectangular-shaped cross section with a top surface 250, a bottom surface 252, an inner surface 254, and an outer surface 256. The second part 248 forms the entire inner surface 254 as well as portions of the top surface 250 and bottom surface 252 of the insert ring 228, and thus has a cross section which is in the shape of an inverted “L.” The cross section of the first part 246 is in the shape of a complementary “L” so that the first and second parts 246, 248 have a combined cross section which is generally rectangular in shape. The width w1 of the second part 248 at the location which forms a portion of the bottom surface 252 is approximately 20% of the overall width of the bottom surface 252, and thus is substantially thicker than a film layer. Similarly, the width w2 of the second part 248 at the location which forms a portion of the top surface 250 comprises approximately 45% of the overall width of the top surface 250.

FIG. 7b shows a composite member insert ring 258 comprised of a first part 260 constructed of a first material and a second part 262 constructed of a second material having a greater electrical impedance than the first material. The insert ring 258 has a generally rectangular cross section with a top surface 264, a bottom surface 266, an inner surface 268, and an outer surface 270. The cross sections of both the first and second parts 260, 262 are each generally rectangular in shape so that these parts have a combined cross section which also is generally rectangular in shape. The second part 262 forms the entire inner surface 268 as well as portions of the top and bottom surfaces 264, 266 of the insert ring 258. The width w of the second part 262 which forms the portions of the top and bottom surfaces 264, 266 is approximately 45% of the overall width of these surfaces. Thus the second part 262 comprises a substantial portion of the over-all volume of the insert ring 258.

FIG. 7c shows a composite member insert ring 271 comprised of a first part 272 constructed of a first material and a second part 274 constructed of a second material having a greater electrical impedance than the first material. The insert ring 271 has a generally rectangular cross section with a top surface 276, a bottom surface 278, an inner surface 280, and an outer surface 282. The second part 274 forms the entire inner and bottom surfaces 280, 278, and portions of the top and outer surfaces 276, 282 of the insert ring 271. The cross section of the second part 274 is generally rectangular in shape with one corner removed so that a ledge 284 is formed. The cross section of the first part 272 is generally rectangular in shape and mates with the ledge 284 of the second part 274 so that when viewed together, the first and second parts 272, 274 have a generally rectangular cross section. Thus the second part 274 comprises a greater portion of the over-all volume of the insert ring 270 than does the first part 272.

The novel insert rings or members disclosed herein can be used in various types of chambers including chambers having powered bottom pedestals or electrodes, such as etch chambers, PVD chambers and CVD chambers. However these rings may be especially useful in etch chambers where the RF bias voltage to the wafer can be the greatest, thus likely giving rise to generally greater electrical arcing and electron emission problems.

It should be noted that the configuration and geometries of the top ring, insulating ring and insert ring are presented for illustration purposes only. The improved and novel insert ring may be constructed in other suitable configurations and geometries in which the surfaces that are immediately adjacent to the wafer, the wafer support, the insulating ring, or to all of these components are preferably made of an insulating material, i.e. a material that has a higher impedance than the remaining portion of the insert ring. For example, rather than an integrated piece, an alternative embodiment of an insert ring may comprise two pieces, one of which is adjacent to the wafer or to the ESC perimeter edge or both, and is constructed of a material having a higher impedance property. The other piece could be manufactured of a more conductive material.

While the description above refers to particular embodiments of the present invention, it will be understood that many modifications may be made without departing from the spirit thereof. The claims are intended to cover such modifications as would fall within the true scope and spirit of the present invention. The presently disclosed embodiments are therefore to be considered in all respects as illustrative and not restrictive, the scope of the invention being indicated by the claims rather than the foregoing description, and all changes which come within the meaning and range of equivalency of the claims are therefore intended to be embraced therein.

1-49. (canceled)

50. A method for assembling an apparatus for use in semiconductor wafer processing, comprising the steps of:
providing a process chamber having a chamber cavity;
providing an electrostatic chuck (ESC) for holding a wafer in the cavity; and
positioning an insert adjacent to the ESC, the insert comprising:
a composite member comprised of a first material and a second material, the second material having a greater electrical impedance than the first material;
the composite member having a first surface which is adapted to be disposed adjacent to one of the ESC and the wafer; and
the first surface being made of the second material having a thickness in excess of 100 Å.

51. The method of claim 50 wherein the composite member has a second surface which is adapted to be disposed adjacent to the other of the ESC and the wafer and wherein the second surface is made of the second material having a thickness in excess of 100 Å.

52. The method of claim 50 wherein the first surface is comprised of a film layer.

53. The method of claim 51 wherein the first and second surfaces are comprised of a film layer.

54. The method of claim 50 wherein the second material is SiO₂, and the first material is one of SiC, Al₂O₃, Y₂O₃ and Si having a purity of at least 99% Si.

55. The method of claim 51 wherein the second material is SiO₂, and the first material is one of SiC, Al₂O₃, Y₂O₃ and Si having a purity of at least 99% Si.

56. The method of claim 50 wherein the composite member is generally annular in shape.

57. A method for assembling an apparatus for use in semiconductor wafer processing, comprising the steps of:
providing a process chamber having a chamber cavity;
providing a wafer support for holding a wafer in the cavity, the wafer support having a perimeter edge; and
positioning an insert adjacent to the wafer support perimeter edge, the insert comprising:
a member having a generally annular shape and being constructed of a first material;
the member having a top surface of a generally planar shape, a bottom surface of a generally planar shape, an outer surface of a generally cylindrical shape and an inner surface of a generally cylindrical shape; and
the member having a layer of a second material having a thickness in excess of 100 Å and a greater electrical impedance than the first material, the layer being disposed on one of the top surface, the bottom surface, the outer surface and the inner surface.

58. The method of claim 57 wherein the layer is disposed on another of the top surface, the bottom surface, the outer surface and the inner surface.

59. The method of claim 58 wherein the layer is disposed on another of the top surface, the bottom surface, the outer surface and the inner surface.

60. The method of claim 59 wherein the layer is disposed on another of the top surface, the bottom surface, the outer surface and the inner surface.

61. The method of claim 57 wherein the first material is one of SiC, Al₂O₃, Y₂O₃ and Si having a purity of at least 99% Si, and the second material is SiO₂ having a purity of at least 99% SiO₂.

62. The method of claim 58 wherein the first material is one of SiC, Al₂O₃, Y₂O₃ and Si having a purity of at least 99% Si, and the second material is SiO₂ having a purity of at least 99% SiO₂.

63. The method of claim 57 wherein the layer has a thickness in excess of 1,000 Å.

64. The method of claim 58 wherein the layer has a thickness in excess of 1,000 Å.

65. A method for processing a semiconductor wafer, comprising:
providing a process chamber having a chamber cavity;
providing a wafer support having a perimeter edge and adapted to support the wafer in the cavity;
providing an insert for use in the process chamber, the insert having a generally annular shape and being constructed of a first material, the insert further having a top surface of a generally planar shape, a bottom surface of a generally planar shape, an outer surface of a generally cylindrical shape and an inner surface of a generally cylindrical shape;
the insert being adapted for placement in the chamber so that at least a part of the inner surface is adjacent to the wafer support perimeter edge; and
the insert further having a layer of a second material having a thickness in excess of 100 Å and having a greater electrical impedance than the first material, the layer being disposed on one of the top surface, the bottom surface, the outer surface and the inner surface; and
placing the wafer onto the wafer support.

66. The method of claim 65 wherein the layer is disposed on another of the top surface, the bottom surface, the outer surface and the inner surface.

67. The method of claim 66 wherein the layer is disposed on another of the top surface, the bottom surface, the outer surface and the inner surface.

68. The method of claim 67 wherein the layer is disposed on another of the top surface, the bottom surface, the outer surface and the inner surface.

69. The method of claim 65 wherein the layer has a thickness in excess of 1,000 Å.

70. The method of claim 66 wherein the layer has a thickness in excess of 1,000 Å

71-76. (canceled)
